(19) United States
(12) Patent Application Publication
(10) Pub. No.: US 2013/0257235 A1
(43) Pub. Date: Oct. 3, 2013

(54) ELECTRONIC DISPLAY

(71) Applicants: Jeff Haliburton, Brookings, SD (US); Brad Rinschen, Brookings, SD (US); John W. Syrstad, Brookings, SD (US); Pete McMahon, Brookings, SD (US); Brian Iwerks, Brookings, SD (US)

(72) Inventors: Jeff Haliburton, Brookings, SD (US); Brad Rinschen, Brookings, SD (US); John W. Syrstad, Brookings, SD (US); Pete McMahon, Brookings, SD (US); Brian Iwerks, Brookings, SD (US)

(21) Appl. No.: 13/754,089

(22) Filed: Jan. 30, 2013

Related U.S. Application Data
(60) Provisional application No. 61/592,250, filed on Jan. 30, 2012.

(51) Int. Cl. H05K 5/00; A47B 81/06

(52) U.S. Cl. CPC H05K 5/0017; A47B 81/06
USPC 312/7.2

(57) ABSTRACT

An electronic display includes one or more face panel displays. Each face panel display includes a face panel, one or more stiffeners mounted to the face panel, and a polycarbonate panel sandwiched between the stiffeners and the face panel. The polycarbonate panel is bent to define first and second side surfaces and the polycarbonate panel follows a contour of the face panel such that a front face of the polycarbonate panel abuts a back surface of the face panel and the first and second side surfaces abut corresponding side surfaces of the face panel.

### PRIORITY OF INVENTION

This application claims priority of invention under 35 U.S.C.§119(e) of U.S. Provisional Application No. 61/592,250, filed Jan. 30, 2012, which is incorporated herein by reference in its entirety.

### FIELD

The present invention relates to displays, and more specifically to an electronic display.

### BACKGROUND

Some front access full matrix signage used large single panel top hinged lift face panels that are ungainly and awkward to open and close, difficult to seal against the elements, insects and the like, as well as involving an inordinate amount of time to gain access thereinto. Another concern is for the safety of technicians where support of a horizontally attached large heavy panel over the area where technicians are working on the display can be in danger if the support structural integrity is compromised.

Other prior art devices used displays with multiple vertically hinged doors, but the pixels spacing at the vertical seams between doors was excessive due to large gaps between panels that allowed the doors to pivot open without incurring mutual door interference at adjacent door edges. Weather sealing provided by this design was very poor as the weather seals were small and thin in order to promote close juxtaposition of pixels from door-to-door. Other signage using vertical hinges included large gaps in the LED matrix due to interceding structure of the door panel. These gaps forced the pixel pitch to increase noticeably between face panels on all but the largest pixel pitches.

### SUMMARY

An electronic display includes one or more face panel displays. Each face panel display includes a face panel, one or more stiffeners mounted to the face panel, and a polycarbonate panel sandwiched between the stiffeners and the face panel. The polycarbonate panel is bent to define first and second side surfaces and the polycarbonate panel follows a contour of the face panel such that a front face of the polycarbonate panel abuts a back surface of the face panel and the first and second side surfaces abut corresponding side surfaces of the face panel.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a perspective view of an electronic display having vertically hinged face panel doors, in accordance with one embodiment;

FIG. 2 is a close-up detail of the area between two of the face panel doors of the electronic display of FIG. 1.

FIG. 3 is a perspective view of the electronic display of FIG. 1 with an open face panel door;

FIG. 4A is a rear perspective view of a face panel door, in accordance with one embodiment;

FIG. 4B is a rear exploded view of the face panel door of FIG. 4A;

FIG. 5 is a top exploded view of a face panel door, in accordance with one embodiment;

FIG. 6 is a top cross-section view of a face panel door, in accordance with one embodiment;

FIG. 7 is a side cross section view of the face panel door;

FIG. 8 is a side view of a shroud and latch for a face panel door, in accordance with one embodiment;

FIG. 9 is a metal form for forming a face panel, in accordance with one embodiment;

FIG. 10 is a perspective view of a walk-in electronic display, in accordance with one embodiment;

FIG. 11 is a rear exploded view of a face panel for the walk-in electronic display of FIG. 10.

FIG. 12 shows a schematic of an active traffic management system, in accordance with one embodiment.

### DETAILED DESCRIPTION

### Face Panel for Electronic Display

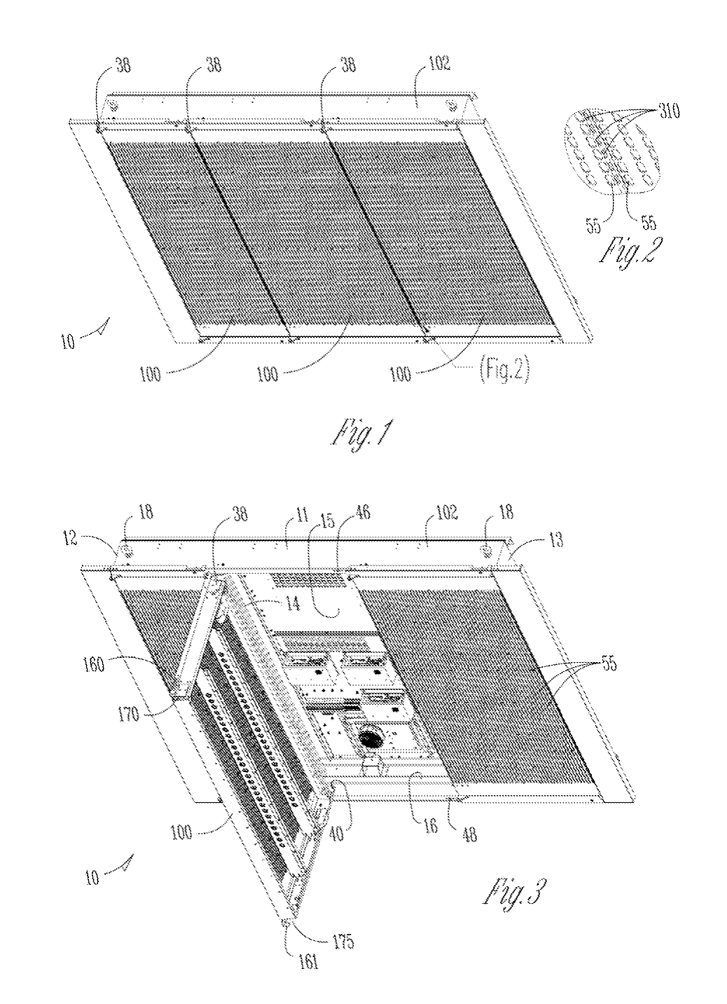

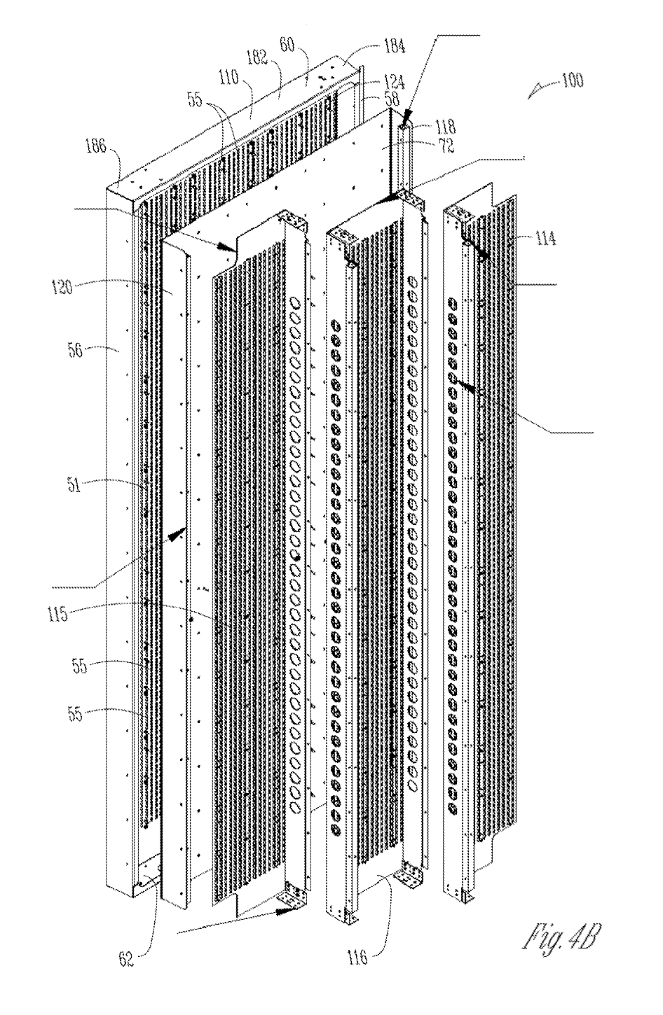

FIG. 1 is a perspective view of an electronic display 10 having vertically hinged face panel doors 100, in accordance with one embodiment; and FIG. 3 is a perspective view of the electronic display 10 with an open face panel door 100.

The electronic display 10 includes a frame 102. The frame 102, to which multiple components are aligned and secured, generally includes configured channels including a top channel 11, opposed end channels 12 and 13, and a bottom channel 16. A plurality of vertically aligned formed channels 14 extend and are secured between the top channel 11 and the bottom channel 16 to provide for support between the top channel 11 and the bottom channel 16 and to serve partially as a mounting structure for a back panel 15. The back panel 15, which accommodates electronic circuitry and which has multiple vents, is secured to the rear perimeter of the frame 102. Lifting lugs 18 are secured to the frame 102.

The upper portion of a plurality of similarly constructed face panel doors 100 are hinged and rotatingly secured to the top channel 11 of the frame 102 by the use of a plurality of top hinge bracket assemblies 38 and the lower portion of the plurality of face panel doors 100 are hinged and rotatingly secured to the bottom channel 16 of the frame 102 by the use of a plurality of bottom hinge bracket assemblies 40.

A plurality of robust and rugged top latch assemblies 170 are distanced from the top hinge bracket assemblies 38 along the plurality of face panel doors 100 and suitably secured to the upper front of the face panel doors 100.

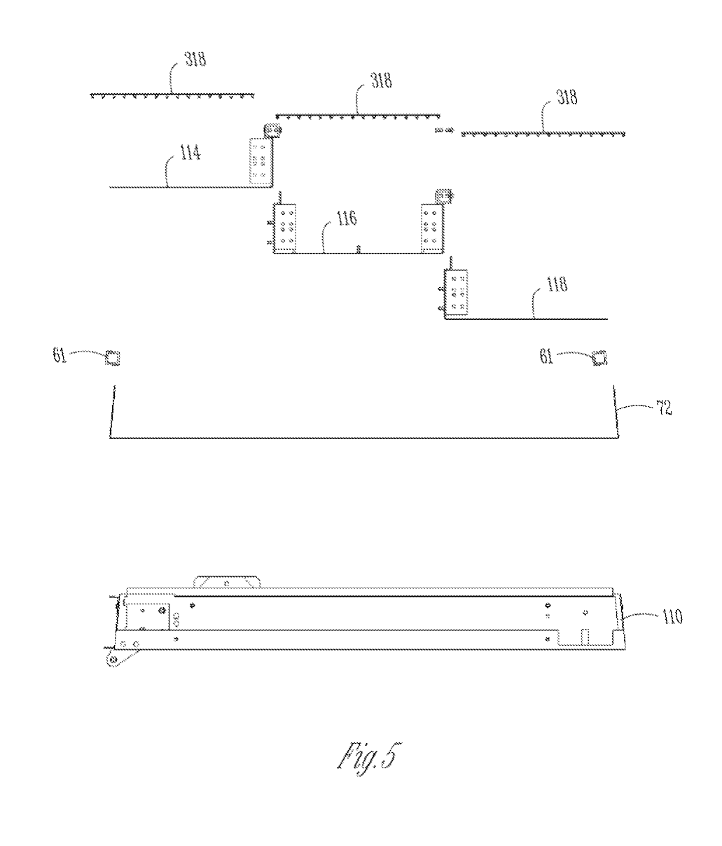

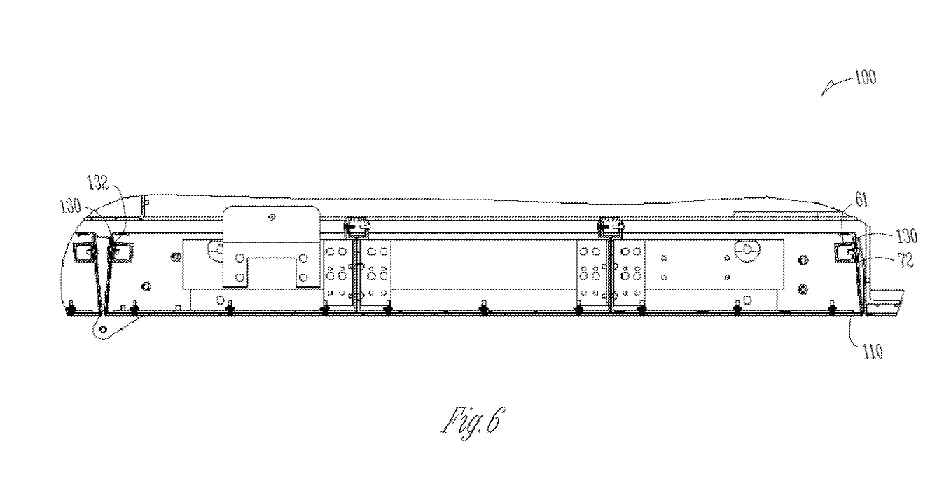

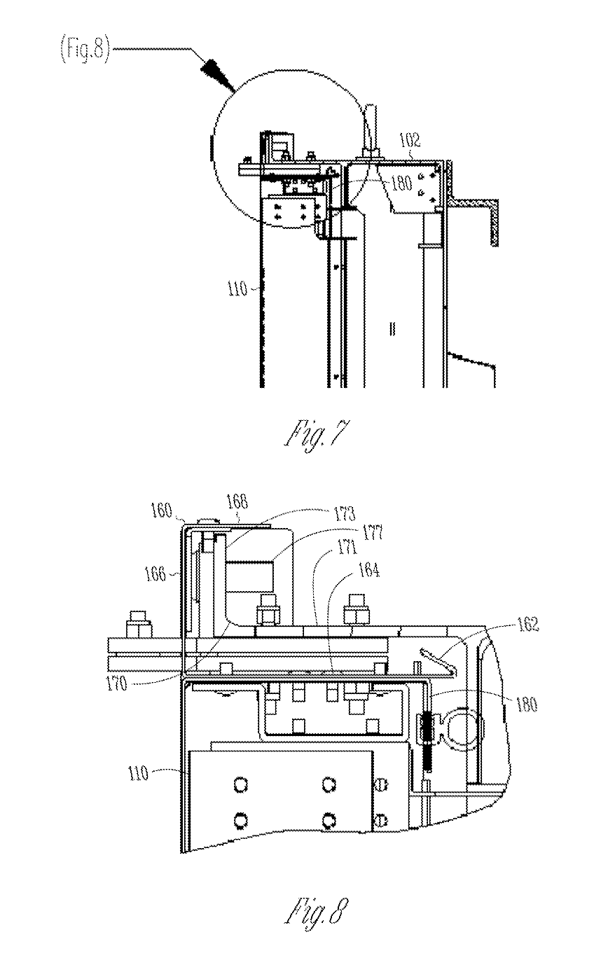

A plurality of bottom latch assemblies 175 are distanced from the bottom hinge bracket assemblies 40 along the plurality of face panel doors 100 and suitably secured to the lower front of the face panel doors 100. When the face panel doors 100 are in the closed position, the top latch assemblies 170 and the bottom latch assemblies 175 are aligned with a plurality of top catch assemblies 46 and a plurality of bottom catch assemblies 48 located in the top channel 11 and the bottom channel 16, respectively, in order that mutual engagement therewith can be effected. FIGS. 4A, 4B, 5, and 6 show further aspects of the face panel door 100. FIG. 4A is a rear perspective view of the face panel door 100; FIG. 4B is a rear exploded view of the face panel door 100; FIG. 5 is a top exploded view of the face panel door; and FIG. 6 is a top cross-section view of the face panel door 100.

The face panel door 100 includes a face panel 110 having a front wall 51 and opposed side panels 56 and 58 and opposed parallelogram shaped top and bottom panels 60 and 62, respectively, which are formed at various angles extending inwardly from the face panel 110 the top view of which is shown in FIG. 5. The face panel 110 includes a plurality of holes 55 for viewing of LED pixels located on LED display modules 318. The opposed side panels 56 and 58 and opposed top panels 60 and 62 include rearwardly located lips 56A, 58A, 60A and 62A, respectively, at the rearward portion thereof. The lips 56A, 58A, 60A and 62A are parallel to the front wall 51 of the face panel 110.

Other components of the face panel door 100 include the top hinge bracket assembly 38 attached to the top surface at one end of the top panel 60 and the bottom hinge bracket assembly 40 attached to the bottom surface at one end of the bottom panel 62.

Another component of the front panel doors 100 is a seal, preferably of foam or soft rubber or plastic, having a broad base and a low profile for minimum compression distortion which seal is secured to the rearwardly located lips 56A, 58A, 60A and 62A for subsequent sealing of the front panel doors 100 upon closure with structures, such as, but not limited to, portions of the top channel 11, the bottom channel 16, the end channels 12 and 13.

Attached to the top and bottom surface of the face panel 110 are a top shroud 160 and a bottom shroud 161, respectively.

FIG. 4A, 7, and 8 shows further details of the top shroud 160. FIG. 7 is a side cross section view of the face panel door 100; and FIG. 8 is a side view of the shroud and the latch 170, in accordance with one embodiment.

The shroud 160 is configured to prevent water infiltration into the electronic display 10. The shroud 160 includes a rear wall 162 extending upward from the face panel door 110. The rear wall 162 is configured to prevent moisture from entering the electronic display 10. When the face panel door 100 is closed, the rear wall 162 hangs over the back edge of the face panel 110 and is located beyond a seam 180 between the frame 102 and the face panel door 100 to help direct any water away from the seam. In one example, the rear wall 162 extends upward at an acute angle relative to a bottom wall 164 of the shroud 160. The shroud 160 includes the bottom wall 164, the rear wall 162, and a front wall 166 extending upwards perpendicularly from the bottom wall 164 and a top wall 168 extending inward from the front wall 166.

Other components of the face panel door 100 include the top latch assembly 170 attached to the upper forward facing surface of the face panel 110 and located behind shroud 160, and the similarly constructed bottom latch assembly 175 attached to the lower forward facing surface of the face panel 110 and located behind shroud 161. Both latch assemblies 170, 175 can be hidden latches which are not visible when the face panel door 100 is closed. In one example, the latches 170, 175 are located behind shrouds 160, 161 respectively. For example, the latch 170 can be located behind the front wall 166 of the top shroud 160 and be configured to mate with the latch receiver 46 located on the frame 102. The latch 170 includes an L-shaped body including a first wall 171 mounted to the top of the face panel door 110 and a second wall 173 extending upward perpendicularly from the first wall 171 and proximate to or abutting the front wall 166 of the shroud 160. A latch pin 177 extends perpendicularly from the second wall 173 and is configured to engage with the corresponding latch receiver 46 on the front of the frame 102 of the electronic display 10 (See FIG. 1). The hidden latch(s) 170, 171 allow for a more aesthetic appearance since the shrouds block the latch mechanisms from view.

Referring again to FIGS. 4A, 4B, 5, and 6 each face panel display door 100 includes the face panel 110, one or more vertical stiffeners 114, 115, 116 mounted to the face panel 110 and a polycarbonate panel 72 sandwiched between the vertical stiffeners 114, 115, 116 and the face panel 110. The polycarbonate panel 72, preferably clear and having hardware accommodation holes, is aligned and secured over rearwardly extending hardware and mates to the rear surface of the face panel 110. The polycarbonate panel 72 is located behind the multiple viewing hole face sheet panel 110 but in front of the LED (light emitting diode) modules 318 in each of the multiple vertically hinged face panel doors 100.

In one example, the polycarbonate panel 72 can be bent or otherwise formed to define first and second side surfaces 118, 120 and the polycarbonate panel 72 follows a contour of the face panel 110 such that a front face 122 of the polycarbonate panel 72 abuts a back surface 124 of the face panel 110 and the first and second side surfaces 118, 120 abut corresponding inside surfaces of walls 56, 58 of the face panel 110. Structural tubes 61 can be mounted at the ends of the polycarbonate panel 172 to add structural strength to the panel. A sealant 130, such as a silicone, can run along a perimeter of the polycarbonate panel 72 at the seam 132 between an edge of the polycarbonate panel 72 and the side surfaces 126, 128 of the face panel 110. This structure allows for a tighter pixel pitch than previous displays. By bending the polycarbonate panel 72, the silicone sealant 130 is placed near the back of the face panel 110 instead of at the front of the face panel 110, as in the case of a flat polycarbonate panel. When the silicone sealant is at the front of the face panel, the silicone blocks the view of any pixels that are close to the edge of the display. In contrast, the present structure allows for pixel to be right up against the edges of the face panel 110 since the silicone sealant 130 is behind the LEDs.

In one example, the face panel display 110 includes a curved top surface 60, such that the center 182 is higher than either edge 184, 186. This allows moisture to drain towards the side of the door 100 and not pool on top where it may infiltrate.

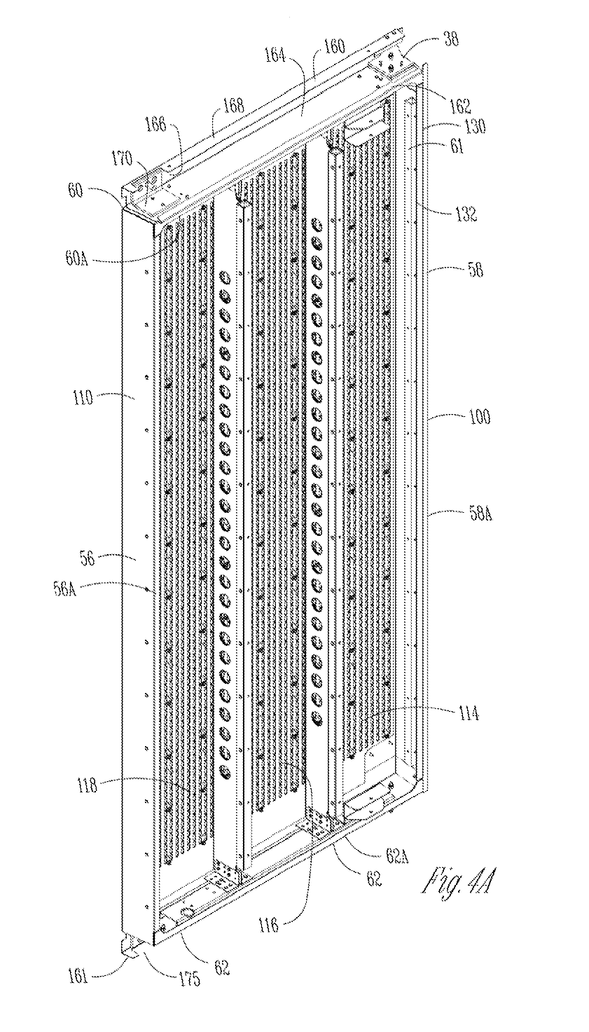

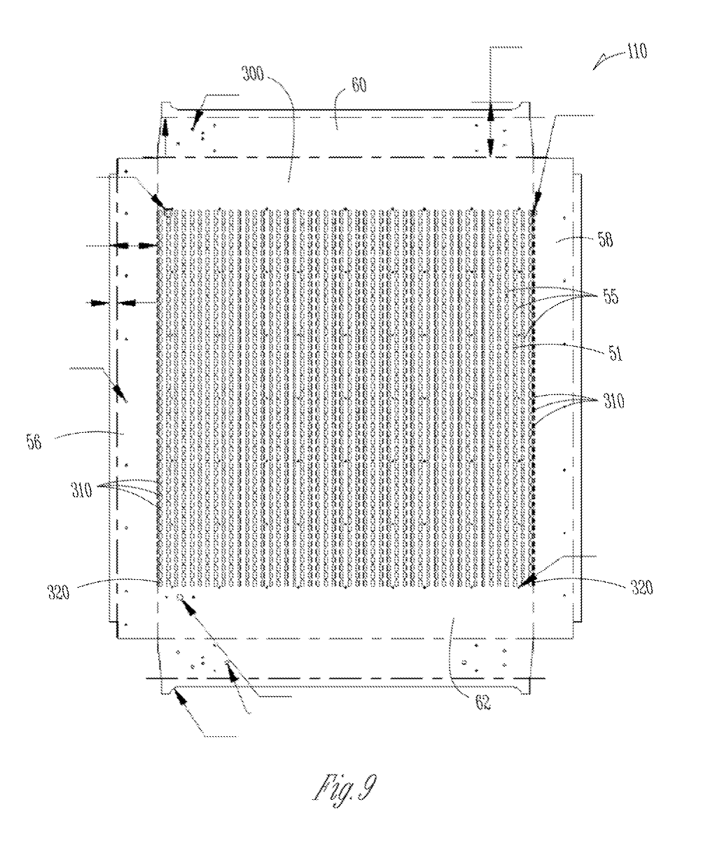

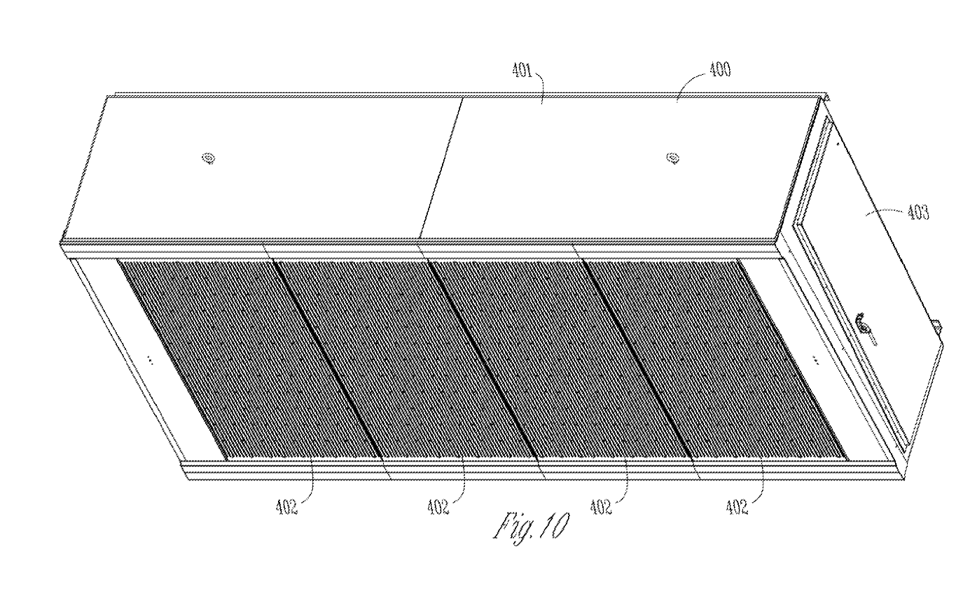

FIG. 9 shows a metal form 300 for forming the face panel 110. In this example, the form 300 includes the front wall 51 and a plurality of side walls 56, 58, 60, 62 which can be bent at an angle from the front wall 51. Here, the face panel 110 form 300 includes a plurality of relief cuts 310 located along the bend lines 320 of at least one of the plurality of side walls 56, 58, 60, 62. In one example, the plurality of relief cuts 310 are located along the bends lines 320 between at least the first side wall 56 and the front wall 51 and a second side wall 58 and the front wall 51. Referring also to FIG. 2, the relief cuts 310 allow for a much sharper bend than bending metal without the relief cuts. Again, this allows for a tighter pixel pitch since the corner edges of the face panel 110 are so sharp, the holes 55 of adjacent doors can be very close and thus the pixels can be located right at the edge without being blocked.

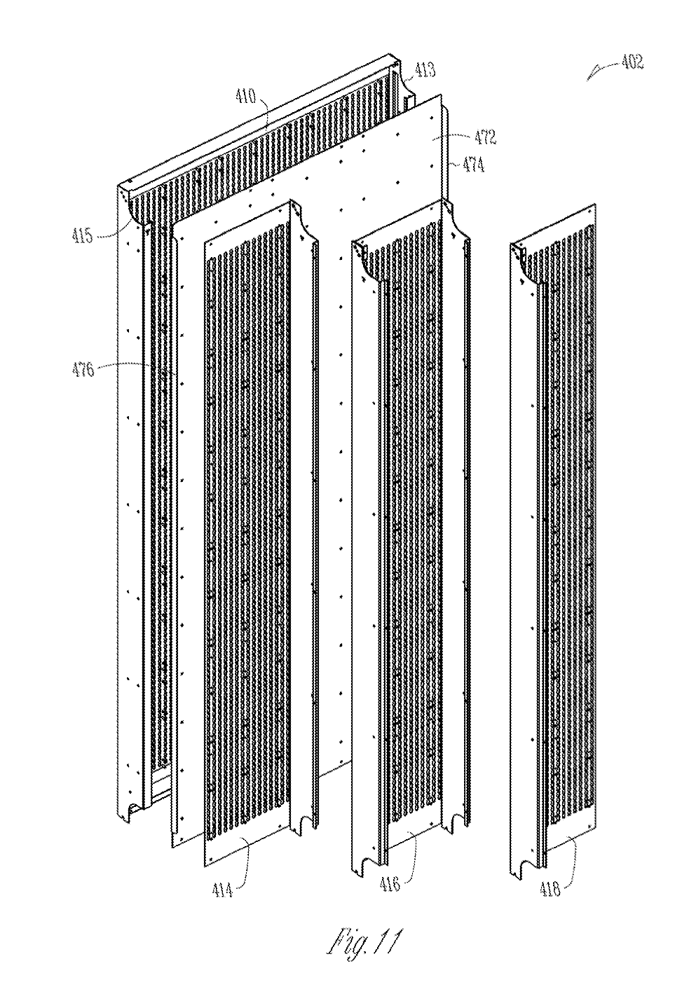

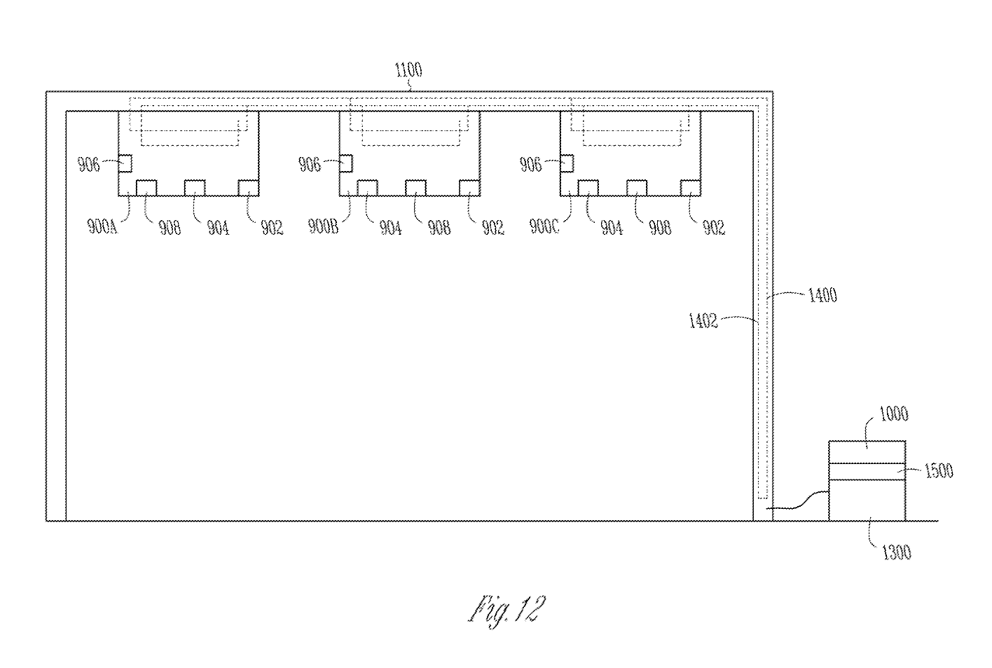

FIGS. 10-11 show a face panel assembly 402 configured for a walk-in electronic display 400. FIG. 10 is a perspective view of the walk-in electronic display 400, in accordance with one embodiment; and FIG. 11 is a rear exploded view of a face panel 402 for the walk-in electronic display 400.

The walk-in electronic display 400 includes a main cabinet 401 having an access door 403 and a plurality of face panel assemblies 402 mounted to the main cabinet 401.

The face panel assembly 402 includes a face panel 410, vertical stiffeners 414, 416, 418, and a polycarbonate panel 472. Some features discussed above, for the face panel door 110, can also apply to the walk-in face panel assembly 402. For example, the face panel 410 can be formed with relief cuts to allow for shaper corners, thus allowing for adjacent face panels assembly 402 to be very close to each other. The polycarbonate panel 472 can be bent so that the side surfaces 474, 476 of the polycarbonate panel 472 abut side walls 413, 415 of the face panel 410. As discussed above, such structures allow for a tighter pixel pitch than previous designs.

### Active Traffic Management System

FIG. 12 shows a schematic of an active traffic management system, with a plurality of electronic displays 900A, 900B, and 900C located over three lanes of a freeway, for example. In some examples, the electronic displays 900A, 900B, and 900C can include features of the electronic display 100, discussed above. The electronic displays can be incorporated into an active traffic management (ATM) electronic sign display. In such an ATM system the signs are located over a multi-lane highway with a separate display over each lane of traffic. Each individual display can provide information that pertains to each given lane.

In various examples, the ATM system includes the following specs:

### Electrical:

Ground mount power:
a. A 24VDC bus
b. Up to 35′ between ground mount traffic cabinet 1000 and signs 900A-900C.
c. One traffic cabinet 1000 to power up to 8 lane control signs 900A-900C.
d. Redundant power supplies

### Hardware/Control:

1. Multi-Sign Control—One controller 1300 for all signs 900A-900C on gantry 1100.

2. One controller 1300 for similar sign types 900A-900C.

3. System Dimming control
a. All signs 900A-900C on one structure will be at same intensity level for LEDs

4. Light sensor 902 mounted on each sign module 900A-900C
a. Address of sign module 900A-900C will determine if the sensor 902 is reading that module sensor 902 value.

5. I/O 904 on sign module 900A-900C for door detection, etc.

6. The controller 1300 can provide for automatic LED voltage adjustment to minimize each sign module 900A-900C power (compensates for LED voltage change due to temperature, LED variations, etc.) (This allows for lower power consumption since the LED voltage level does not need to be set at a high default voltage to ensure proper voltage for all conditions.)

7. Sign module 900A-900C temperature sensors 906 used for ventilation control.

8. Sign module 900A-900C temp sensors 908 used for viewing temperature map of display via Vanguard software

9. Sign module 900A-900C voltages reported to controller 1300 (Input voltage(s), LED voltages, etc.)

10. One example uses a VCB using PL6: redundant data path from controller 1300 to sign—Self-healing ring for fiber.

11. Redundant data can be sent through data paths 1400 and 1402 so if one sign malfunctions, the data can still be sent to other signs on the gantry.

In one example, the ground mounted power system 1500 is located within a traffic cabinet 1000 located by the side of the road or up to 35 feet away.

### Additional Notes

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The claimed invention is:

1. An apparatus comprising:
an electronic display including one or more face panel displays;
each face panel display including a face panel, one or more stiffeners mounted to the face panel and a polycarbonate panel sandwiched between the stiffeners and the face panel;
wherein the polycarbonate panel is bent to define first and second side surfaces and the polycarbonate panel follows a contour of the face panel such that a front face of the polycarbonate panel abuts a back surface of the face panel and the first and second side surfaces abut corresponding side surfaces of the face panel.

2. The apparatus of claim 1, wherein the face panel is a face panel configured for a walk-in electronic display.

3. The apparatus of claim 1, wherein the face panel display is a vertically hinged face panel door.

4. The apparatus of claim 1, including a sealant located at the seam between an edge of the polycarbonate panel and the side surfaces of the face panel.

5. The apparatus of claim 1, wherein the face panel is formed of a metal form, and the metal form includes a plurality of relief cuts along a plurality of bend lines of the metal form.

6. The apparatus of claim 1, including a shroud attached to the top of the face panel display, the shroud configured to prevent water infiltration into the electronic display.

7. The apparatus of claim 1, including a latch located behind the shroud.

8. The apparatus of claim 1, wherein the face panel display includes a curved top surface.

9. An apparatus comprising:
an electronic display including a frame and one or more face panel doors vertically mounted to the frame;
each face panel door including a shroud mounted to the top of the face panel door, the shroud including a rear wall extending upward from the face panel door, wherein the rear wall is configured to prevent moisture from entering the electronic display.

10. The apparatus of claim 9, wherein the rear wall is located beyond a seam between the frame and the face panel door.

11. The apparatus of claim 9, wherein the rear wall extends upward at an acute angle relative to a bottom wall of the shroud.

12. The apparatus of claim 9, wherein the shroud includes the bottom wall, the rear wall, and a front wall extending upwards perpendicularly from the bottom wall and a top wall extending inward from the front wall.

13. The apparatus of claim 12, further comprising a latch located behind the front wall of the shroud and configured to mate with a latch receiver located on the frame.

14. The apparatus of claim 9, wherein the face panel door includes a curved top.

15. A face panel display comprising:
a face panel including a front wall and a plurality of side walls bent at an angle from the from wall, wherein the face panel includes a plurality of relief cuts located along the bend lines of at least one of the plurality of side walls.

16. The face panel display of claim 15, wherein the plurality of relief cuts are located along the bends lines between at least a first side wall and the front wall and a second side wall and the front wall.
